(19) United States
(12) Patent Application Publication
(10) Pub. No.: US 2026/0305436 A1
(43) Pub. Date: Oct. 1, 2026

(54) MOUNTING HEAD AND MOUNTING APPARATUS HAVING THE MOUNTING HEAD

(71) Applicant: SHIBAURA MECHATRONICS CORPORATION, Yokohama-shi (JP)

(72) Inventors: Takuya OHE, Yokohama-shi (JP); Toshifumi OKAWARA, Yokohama-shi (JP); Naoki SETO, Yokohama-shi (JP); Kyota KUROIWA, Yokohama-shi (JP)

(73) Assignee: SHIBAURA MECHATRONICS CORPORATION, Yokohama-shi (JP)

(21) Appl. No.: 19/562,691

(22) Filed: Mar. 10, 2026

(30) Foreign Application Priority Data
Mar. 28, 2025 (JP) 2025-055505
Nov. 28, 2025 (JP) 2025-209349

(51) Int. Cl. H10W 72/00; H10P 72/00

(52) U.S. Cl. CPC H10W 72/07173; H10P 72/0442

(57) ABSTRACT

According to an embodiment, a mounting head includes a collet having at least one suction hole at a contact surface configured to be in contact with a semiconductor electronic component so that the semiconductor electronic component is curved, and a supporting unit supporting the collet so that the contact surface of the collet is exposed. The supporting unit is configured to supply a gas toward a substrate from outside the contact surface of the collet. The supporting unit may have at least one gas-supplying hole for supplying the gas.

### CROSS-REFERENCE TO RELATED APPLICATIONS

This application claims the benefit of priority to Japanese Patent Applications No. 2025-055505 filed on Mar. 28, 2025, and No. 2025-209349 filed on Nov. 28, 2025, the entire contents of which are incorporated herein by reference.

### BACKGROUND

### Technical Field

An embodiment of the present disclosure relates to a mounting head for mounting semiconductor electronic components onto a substrate and a mounting apparatus equipped with the mounting head.

### Description of the Related Art

A method has been known for mounting semiconductor electronic components (semiconductor chips) manufactured over semiconductor wafers containing single crystal silicon, sapphire, or the like onto a substrate (transfer substrate) in which individually divided semiconductor electronic components are picked up from a semiconductor wafer and mounted onto the substrate. For example, Japanese Laid-Open Patent Application No. 2022-152575 discloses a mounting apparatus which holds a semiconductor electronic component in a curved state using a mounting head capable of contacting a substrate and releases the holding of the semiconductor electronic component by the mounting head in a state where a portion of the semiconductor electronic component is in contact with the substrate, thereby mounting the semiconductor electronic component onto the substrate.

However, when a semiconductor electronic component is held in a curved state using a mounting head, a portion of the semiconductor electronic component is brought into contact with the substrate, and the holding of the semiconductor electronic component by the mounting head is released in this state to mount the semiconductor electronic component, voids may be generated at an edge portion of the semiconductor electronic component. When voids are generated, bonding defects of the semiconductor electronic component may occur, and the yield of semiconductor products may decrease.

### BRIEF SUMMARY

An embodiment of the present disclosure is a mounting head for mounting a semiconductor electronic component onto a substrate. The mounting head includes a collet having at least one suction hole at a contact surface configured to be in contact with the semiconductor electronic component so that the semiconductor electronic component is curved, and a supporting unit supporting the collet so that the contact surface of the collet is exposed. The supporting unit is configured to supply a gas toward the substrate from outside the contact surface of the collet.

### BRIEF DESCRIPTION OF THE SEVERAL VIEWS OF THE DRAWINGS

FIG. 1 is a schematic perspective view showing a method for mounting semiconductor electronic components.

FIG. 2 is a schematic side view of a mounting apparatus according to an embodiment of the present disclosure.

FIG. 3 is a schematic top view of a mounting apparatus according to an embodiment of the present disclosure.

FIG. 4 is a schematic perspective view of a mounting head according to an embodiment of the present disclosure.

FIG. 5 is a schematic side view of a mounting head according to an embodiment of the present disclosure.

FIG. 6 is a schematic side view of a mounting head according to an embodiment of the present disclosure.

FIG. 7 is a schematic cross-sectional view of a mounting head according to an embodiment of the present disclosure.

FIG. 8 is a schematic cross-sectional view of a mounting head according to an embodiment of the present disclosure.

FIG. 9 is a schematic side view showing a method for mounting semiconductor electronic components using a mounting apparatus according to an embodiment of the present disclosure.

FIG. 10 is a schematic cross-sectional view showing a method for mounting semiconductor electronic components using a mounting apparatus according to an embodiment of the present disclosure.

FIG. 11 is a schematic cross-sectional view showing a method for mounting semiconductor electronic components using a mounting apparatus according to an embodiment of the present disclosure.

FIG. 12 is a schematic side view showing a method for mounting semiconductor electronic components using a mounting apparatus according to an embodiment of the present disclosure.

FIG. 13 is a schematic cross-sectional view showing a method for mounting semiconductor electronic components using a mounting apparatus according to an embodiment of the present disclosure.

FIG. 14 is a schematic side view showing a method for mounting semiconductor electronic components using a mounting apparatus according to an embodiment of the present disclosure.

FIG. 15 is a schematic cross-sectional view of a mounting head according to an embodiment of the present disclosure.

FIG. 16 is a schematic cross-sectional view of a mounting head according to an embodiment of the present disclosure.

FIG. 17 is a schematic bottom view of a mounting head according to an embodiment of the present disclosure.

FIG. 18 is a schematic bottom view of a mounting head according to an embodiment of the present disclosure.

FIG. 19 is a schematic cross-sectional view of a mounting head according to an embodiment of the present disclosure.

FIG. 20 is a schematic cross-sectional view of a mounting head according to an embodiment of the present disclosure.

FIG. 21 is a schematic cross-sectional view of a mounting head according to an embodiment of the present disclosure.

FIG. 22 is a schematic cross-sectional view of a mounting head according to an embodiment of the present disclosure.

FIG. 23 is a schematic perspective view of a mounting head according to an embodiment of the present disclosure.

FIG. 24 is a schematic cross-sectional view of a mounting head according to an embodiment of the present disclosure.

FIG. 25 is a schematic bottom view of a mounting head according to an embodiment of the present disclosure.

### DETAILED DESCRIPTION

Hereinafter, each embodiment of the present disclosure is explained with reference to the drawings. The disclosure can be implemented in a variety of different modes within its concept and should not be interpreted only within the disclosure of the embodiments exemplified below.

The drawings may be illustrated so that the width, thickness, shape, and the like are illustrated more schematically compared with those of the actual modes in order to provide a clearer explanation. However, they are only an example, and do not limit the interpretation of the disclosure. In the specification and the drawings, the same reference number is provided to an element that is the same as that which appears in preceding drawings, and a detailed explanation may be omitted. When a portion of a structure is represented, a small-letter of the alphabet is added after a reference number.

In the specification and the claims, unless specifically stated, when a state is expressed where a structure is arranged “over” another structure, such an expression includes both a case where a structure is arranged immediately above the “other structure” so as to be in contact with the “other structure” and a case where the structure is arranged over the “other structure” with an additional structure therebetween.

In the specification and the claims, an expression that “a structure is exposed from another structure” means a state where a portion of the structure is not covered by the other structure and also includes a state where the portion which is not covered by the other structure is covered with another structure. Here, the vertical relationship between the structure and the other structure is irrelevant. In addition, the state expressed by this expression includes a state where the structure is not in contact with the other structure.

### First Embodiment

Hereinafter, a mounting head, a mounting apparatus equipped with the mounting head, and a method of mounting semiconductor electronic components using the mounting apparatus are explained.

### 1. Mounting of Semiconductor Electronic Component

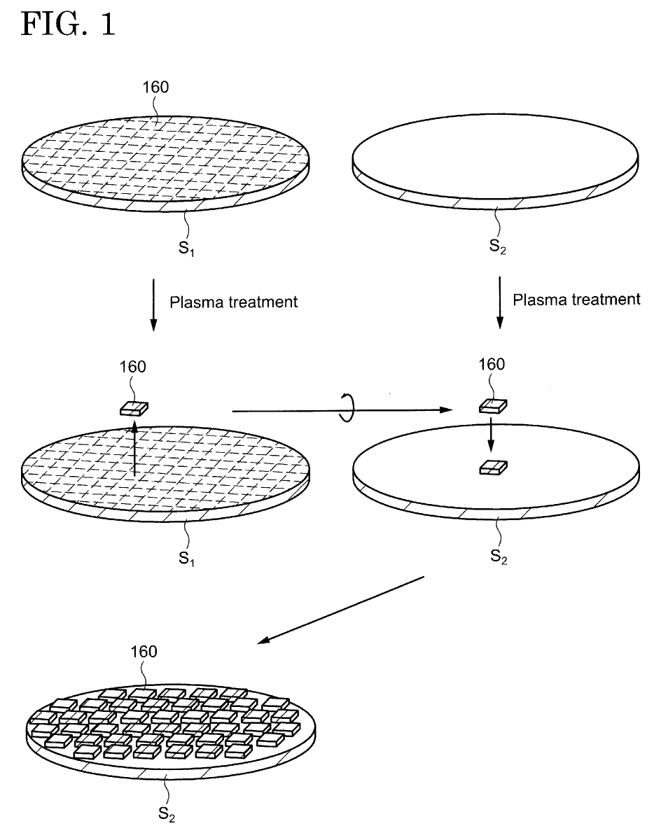

The mounting apparatus in accordance with an embodiment of the present disclosure can be suitably used for mounting semiconductor electronic components, for example, for mounting semiconductor electronic components directly onto a substrate by a method called hybrid bonding. As schematically shown in FIG. 1, a plurality of semiconductor electronic components 160 is formed over a semiconductor wafer S₁. A protective film consisting of silicon oxide is formed over a surface of the semiconductor electronic components 160, and electrodes for receiving a variety of signals are exposed from the protective film. The semiconductor wafer S₁ is divided into individual semiconductor electronic components 160. In this method, an activation process such as a plasma treatment is performed on such a semiconductor wafer S₁ to activate the surface of the protective film so that Si-OH bonds are generated. Meanwhile, a glass substrate, a quartz substrate, or a single-crystal silicon substrate is used as the substrate S₂, and a variety of wirings for supplying signals to the electrodes fabricated over the semiconductor electronic components 160 as well as a protective film consisting of silicon oxide are formed so as to expose electrodes formed over a portion of the wirings. Substrate S₂is also subjected to an activation process such as a plasma treatment, by which the surface of the protective film is activated to form Si-OH bonds. These plasma treatments are called pretreatments and are performed using a pretreatment apparatus which is not illustrated.

The semiconductor electronic components 160 are picked up one by one, flipped upside down, and mounted onto the substrate S₂. As a result, the electrodes of the semiconductor electronic component 160 and the electrodes of the wirings formed over the substrate S₂are brought into contact or come into close contact, and the protective films formed over the semiconductor electronic component 160 and the substrate S₂ are brought into contact with each other. A plurality of semiconductor electronic components 160 can be mounted onto the substrate S₂ by repeating this operation.

The substrate S₂ is then heated. The heating temperature is, for example, equal to or higher than 450 °C and equal to or lower than a melting point, a strain point, or a glass-transition temperature of the substrate S₂. At this time, pressure (e.g., equal to or greater than 0.2 MPa and equal to or less than 5 MPa) may be applied as appropriate. This heat treatment causes the Si-OH bonds on the surface of the protective films formed over the semiconductor electronic component 160 and the substrate S₂ to be condensed to form siloxane bonds and causes the electrodes of the semiconductor electronic component 160 and the electrodes of the substrate S₂to undergo diffusion-bonding. This mechanism allows the semiconductor electronic component 160 to be firmly fixed onto the substrate S₂. In addition, because it is not necessary to form bumps using conductive adhesives such as solder for electrical connection between the electrodes of the semiconductor electronic components 160 and the electrodes of the substrate S₂, the semiconductor electronic components 160 can be mounted onto the substrate S₂ at high density. Therefore, the semiconductor electronic components 160 can be highly integrated by using the hybrid bonding.

Note that although the substrate S₂ is circular or nearly circular in the example shown in FIG. 1, there is no restriction on the shape and size of the substrate S₂, and the substrate S₂ having a variety of shapes such as a rectangle can be used.

### 2. Structure of Mounting Apparatus

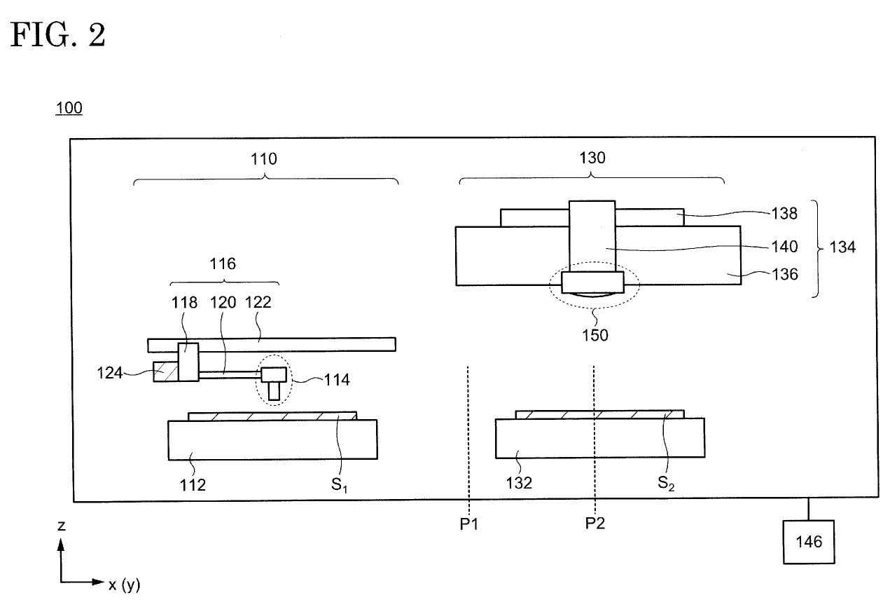

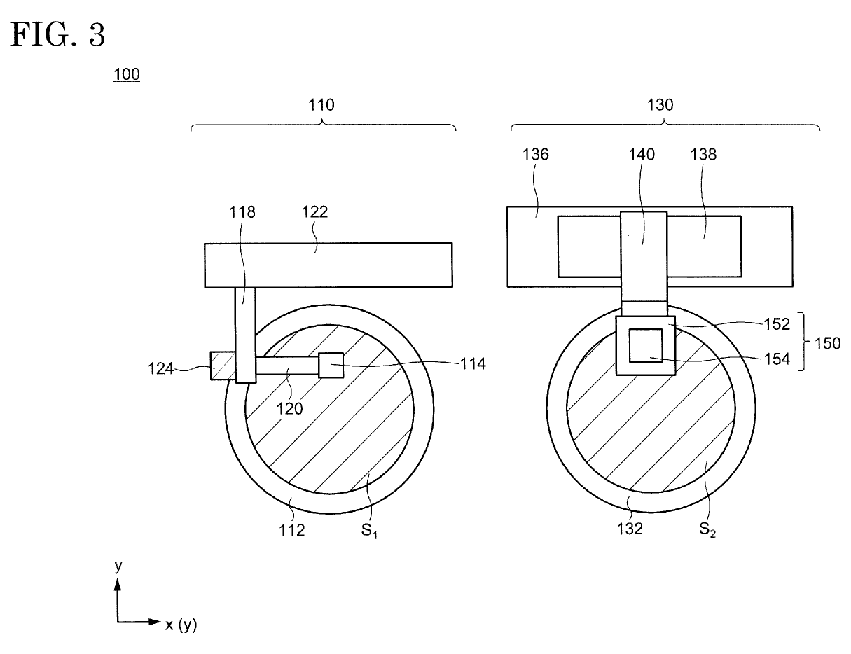

FIG. 2 and FIG. 3 respectively show schematic side and top views of the mounting apparatus 100 according to an embodiment of the present disclosure. The mounting apparatus 100 has a control device 146 as well as a pick-up device 110 and a bonding device 130 controlled by the control device 146. The semiconductor electronic component 160 is removed from the divided semiconductor wafer S₁ by the pick-up device 110 and flipped upside down. The bonding device 130 receives the vertically inverted semiconductor electronic component 160 from the pick-up device 110 and mounts it onto the substrate S₂. Hereinafter, the structures of these components are described in detail. In the following description, the horizontal plane is defined as a xy-plane, and the vertical direction is defined as a z-direction for convenience. The z-direction is the up and down directions. The upward and downward directions may be respectively referred to as a +z-direction and a −z-direction.

### 1-1. Pick-Up Device

The pick-up device 110 has, as its fundamental components, a stage 112 for holding the semiconductor wafer S₁, a pick-up nozzle 114 for sucking and holding the semiconductor electronic component 160, and a moving mechanism 116 for moving the pick-up nozzle 114 in the horizontal direction or the vertical direction. The semiconductor wafer S₁ is placed on the stage 112 through a tray or an adhesive sheet in a separated state into individual semiconductor electronic components 160. Although not illustrated, the stage 112 may be provided with a pin to move the individual semiconductor electronic components 160 in an upward direction (i.e., toward the side of the pick-up nozzle 114). An exhaust device which is not illustrated is connected to the pick-up nozzle 114, by which a negative pressure is generated on the side of a lower end surface of the pick-up nozzle 114 to allow the semiconductor electronic component 160 to be sucked and held by the pick-up nozzle 114. Although not illustrated, the pick-up device 110 may be provided with a moving mechanism for moving the stage 112 in a horizontal plane. It is also possible to move the pin and the stage 112 relative to each other by providing this moving mechanism.

Note that there are no restrictions on the structure of the moving mechanism 116, and any configuration capable of moving the pick-up nozzle 114 in the x, y, and z-directions may be adopted as appropriate. For example, the moving mechanism 116 may be composed of an arm 120 holding the pick-up nozzle 114, a lifting device 118 configured to move the arm 120 in the vertical direction, and a guide frame 122 equipped with a guide rail (not illustrated) for moving the arm 120 in the horizontal direction together with the lifting device 118, and the like as shown in FIG. 2 and FIG. 3. The lifting device 118 is configured to move in the horizontal direction along the guide frame 122, while the guide frame 122 is configured to move the arm 120 in the horizontal direction perpendicular to the extending direction thereof. For example, the lifting device 118 may be a ball-screw mechanism driven by a servo motor. The pick-up nozzle 114 can be moved to any position over the semiconductor wafer S₁ and in the vertical direction by providing such a moving mechanism 116. Note that the vertical direction here is also the direction for approaching and spacing away from the semiconductor wafer S₁ placed on the stage 112.

The pick-up nozzle 114 is configured to rotate about the extending direction of the arm 120 or an axis parallel thereto. Specifically, a flipping mechanism 124 is provided to the lifting device 118. Thus, the pick-up nozzle 114 can flip the semiconductor electronic component 160 sucked and held by the pick-up nozzle 114 upside down. The flipping mechanism 124 is configured to be connected to the arm 120 via the lifting device 118, and the pick-up nozzle 114 is inverted by rotating the arm 120 in the axis direction of the extending direction of the arm 120. Note that the flipping mechanism 124 is, for example, an actuator including a driving source such as a motor.

### 1-2. Bonding Device

The bonding device 130 has a stage 132 for placing the substrate S₂onto which the semiconductor electronic components 160 are mounted, a mounting head 150 for sucking and holding the semiconductor electronic components 160 and mounting them onto the substrate S₂, and a moving mechanism 134 for moving the mounting head 150 in the horizontal direction and the vertical direction. The moving mechanism 134 is further configured to rotate the mounting head 150 about an axis in the z-direction. Although not illustrated in FIG. 2, the bonding device 130 is equipped with an image-capturing device for reading alignment marks formed on the substrate S₂, a gas-supplying source for supplying a humidity-controlled gas, and an exhaust device for creating a reduced pressure for sucking the semiconductor electronic component 160. The gas-supplying source and the exhaust device are connected to the mounting head 150. In addition, the bonding device 130 includes a moving mechanism for moving the stage 132 in the horizontal direction (y-direction).

As the moving mechanism 134, any configuration capable of moving the mounting head 150 in the horizontal direction (x-direction) and the vertical direction (z-direction) may be employed. For example, the moving mechanism 134 may be composed of a lifting mechanism 140 for supporting, lifting, and lowering the head 150, a guide frame 136 provided with rails (not illustrated) for moving the lifting mechanism 140 in the horizontal direction (e.g., x-direction), and a slider 138 configured to move the mounting head 150 together with the lifting mechanism 140 along the rails of the frame 136, and the like as shown in FIG. 2 and FIG. 3. The slider 138 may be configured to move the mounting head 150 in the horizontal direction perpendicular to the extending direction of the guide frame 136 with a ball screw mechanism driven by a servo motor, or the guide frame 136 may be configured to move in that direction. Note that the lifting mechanism 140 is configured to lift and lower the mounting head 150 in the vertical direction by, for example, a ball-screw mechanism driven by a servo motor. The moving mechanism 134 moves the mounting head 150 back and forth between the delivery position P1 and the mounting position P2. At the delivery position P1, the semiconductor electronic component 160 sucked and held by the pick-up nozzle 114 of the pick-up device 110 is delivered to the mounting head 150. At the mounting position P2, the mounting head 150 holds the semiconductor electronic component 160 and further moves in the −z-direction to mount the semiconductor electronic component 160 onto arbitral positions on the substrate S₂.

### 1-3. Structure of Mounting Head

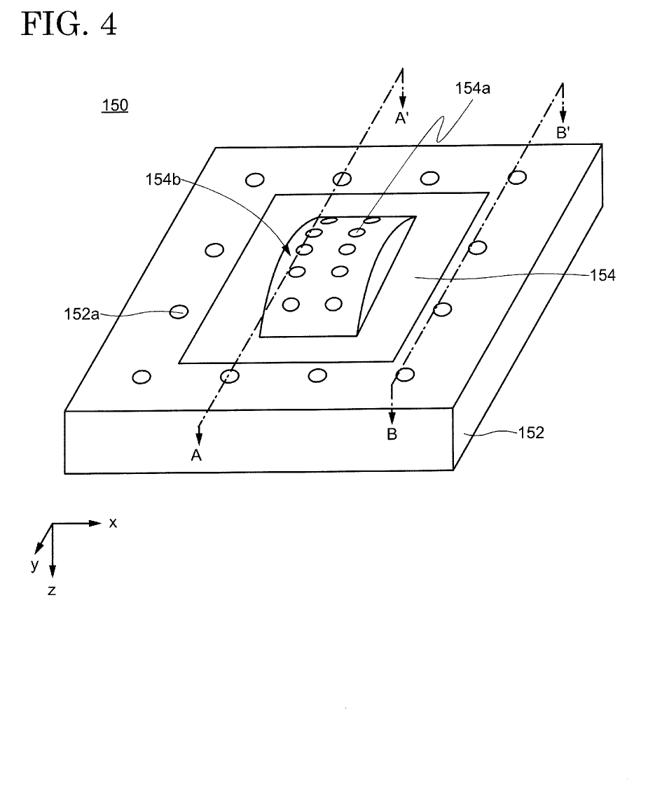

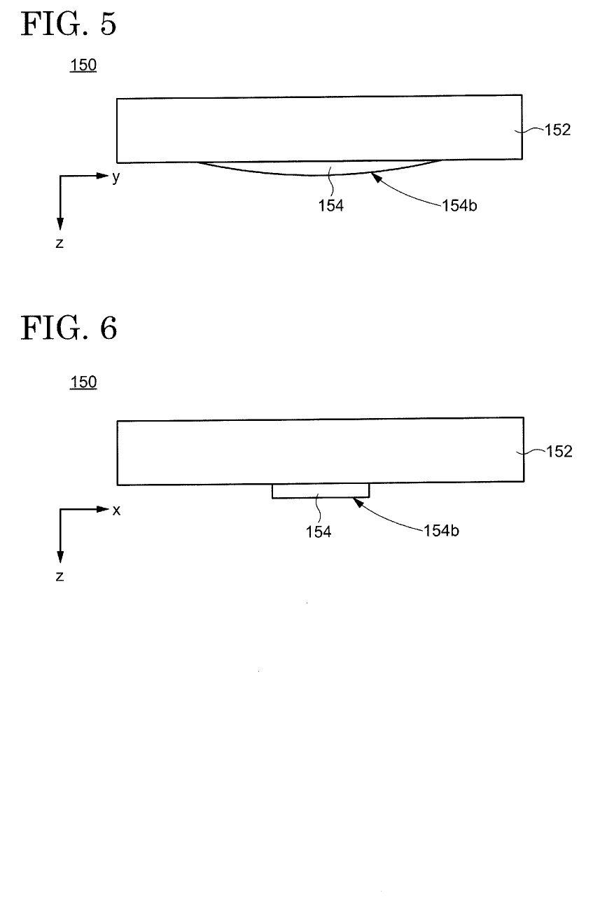

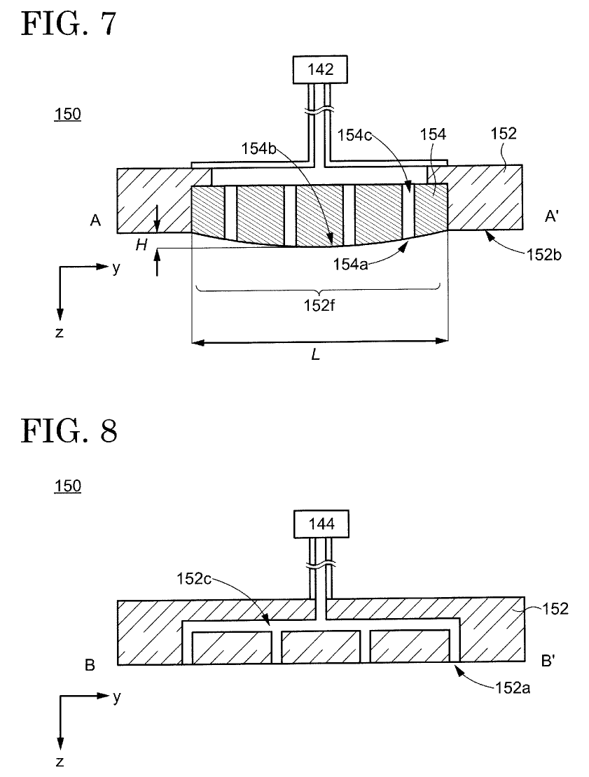

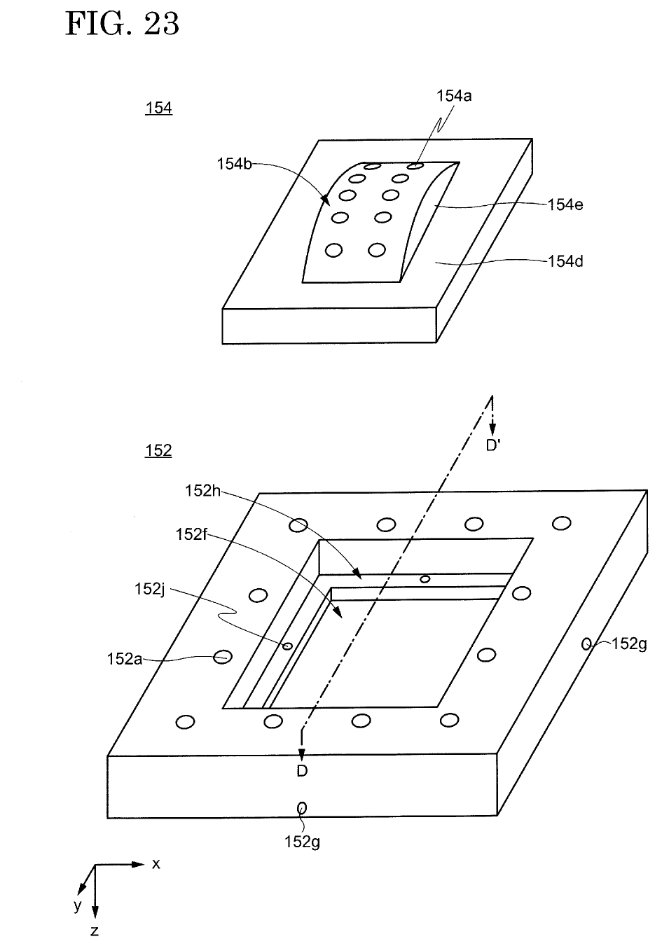

Schematic perspective views of the mounting head 150 are shown in FIG. 4 and FIG. 23, and schematic side views are shown in FIG. 5 and FIG. 6. Schematic cross-sectional views along the chain lines A-A′ and B-B′ of FIG. 4 are respectively shown in FIG. 7 and FIG. 8. FIG. 4 is a perspective view of the mounting head 150 observed from the bottom side, and FIG. 23 is a schematic perspective view showing a state in which a collet 154 and a supporting unit 152 structuring the mounting head 150 are separated. FIG. 7 is a cross-sectional view parallel to the yz-plane passing through a suction hole 154a described below, and FIG. 8 is a cross-sectional view parallel to the yz-plane passing through a gas-supplying hole 152adescribed below.

The supporting unit 152 is a member for supporting the collet 154 and thus has an opening 152f accommodating the collet 154 as shown in FIG. 23. The opening 152f is a through hole and is provided with a step 152h as a surface to support the collet 154. The collet 154 and the supporting unit 152 are fixed to each other, and the supporting unit 152 is arranged to surround the collet 154. However, the supporting unit 152 is configured so that the lower surface 154b of the collet 154 is not covered, i.e., the lower surface 154b of the collet 154, which is a contact surface with the semiconductor electronic component 160, is exposed from the supporting unit 152. The collet 154 and the supporting unit 152 include, for example, a metal such as molybdenum, titanium, tantalum, tungsten, copper, and aluminum or an alloy including a metal selected from these metals.

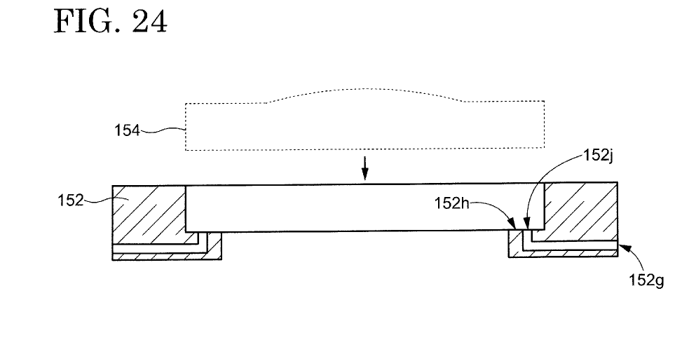

The method of fixing the supporting unit 152 and the collet 154 is arbitrarily determined, and the supporting unit 152 and the collet 154 may be fixed using bolts and screws or using a reduced pressure. For example, as shown in FIG. 23 and the cross-sectional view along the chain line D-D′ thereof (FIG. 24), a plurality of suction holes 152j may be provided to the step 152h to suck the collet 154 from the suction ports 152g connected to the suction holes 152j using an exhaust device which not illustrated. This configuration allows the formation of a negative pressure between the step 152h and the collet 154 to fix the supporting unit 152 and the collet 154.

The collet 154 is a member having a function as a receiving portion receiving the semiconductor electronic component 160 from the pick-up nozzle 114 at the delivery position P1 and further mounting this semiconductor electronic component 160 onto the substrate S₂ at the mounting position P2. The collet 154 has a base portion 154d and a convex portion 154e protruding from the base portion 154d (see FIG. 23), and the lower surface 154b, which is the surface of the convex portion 154e, functions as a surface for holding the semiconductor electronic component 160. This lower surface 154bis also a bottom surface of the collet 154. There is no restriction on the planar shape of the lower surface 154b (the shape in the top view and the shape viewed from the z-direction. The same is applied hereinafter). However, the shape compatible with the shape and the size of the semiconductor electronic component 160 to be mounted is selected. Preferably, the planar shape of the lower surface 154b is a square such as a regular square and a rectangle. Hereinafter, explanations are provided for the case where the planar shape of the convex portion 154e of the collet 154 is rectangular and its longitudinal direction is the y-direction as shown in FIG. 4 and FIG. 23. When the planar shape of the convex portion 154eis rectangular, the longitudinal direction thereof may be parallel or perpendicular to the extending direction of the guide frame 122 of the pick-up device 110 and the guide frame 136 of the bonding device 130 or may intersect the directions of these components at any angle.

As can be understood from FIG. 4, FIG. 5 and FIG. 6, the lower surface 154b is not parallel to the xy-plane but is curved to protrude downwardly. More specifically, the lower surface 154b is curved to protrude downwardly when viewed from the x-direction. Thus, the convex portion 154emay be semi-cylindrical or may be a shape obtained by cutting a cylinder with a plane perpendicular to the bottom surface thereof. Alternatively, the shape of the lower surface 154b viewed from the x-direction may be arc-shaped or V-shaped. In the case of the V-shape, the curved portion thereof is formed by a curve. The semiconductor electronic component 160 is sucked on the lower surface 154b of the collet 154 as described below. Hence, the convex portion 154e is able to suck and hold almost the entire semiconductor electronic component 160 in a curved state on the lower surface 154b of the convex portion 154e without damaging the semiconductor electronic component 160 when the convex portion 154e has the aforementioned shape. Therefore, depending on the size of the semiconductor electronic component 160 to be mounted, the length L (see FIG. 7) in the longitudinal direction may be equal to or less than 100 mm, 75 mm, 50 mm, or 25 mm when the shape of the convex portion 154e in the top view is rectangular. The lower limit of the length L may be selected from a range equal to or greater than 5 mm and equal to or less than 20 mm. When the shape of the collet in a top view is a regular square, the length of one side may be set to be equal to or less than 100 mm, 75 mm, 50 mm, or 25 mm, and the lower limit of the length of one side may be set from a range equal to or greater than 5 mm and equal to or less than 20 mm.

As shown in FIG. 4 and FIG. 23, at least one suction hole 154a is provided at the lower surface 154b of the convex portion 154e to suck and hold the semiconductor electronic component 160. The at least one suction hole 154a may include a plurality of suction holes 154a. When a plurality of suction holes 154a is provided, all of the plurality of suction holes 154a may be arranged on a single line or on a plurality of lines. Alternatively, the plurality of suction holes 154a may have a staggered arrangement. As shown in FIG. 7, the suction holes 154a are connected to the exhaust device 142 through suction channels 154c formed in the collet 154 and reaching the opening 152f of the supporting unit 152. This configuration allows a gas on the side of the lower surface 154b of the collet 154 to be sucked through the suction channels 154c to form a negative pressure on the side of the lower surface 154b. The semiconductor electronic component 160 can be securely sucked and held on the lower surface 154b of the collet 154 by using this negative pressure. In addition, the hold of the semiconductor electronic component 160 can also be released by releasing the negative pressure.

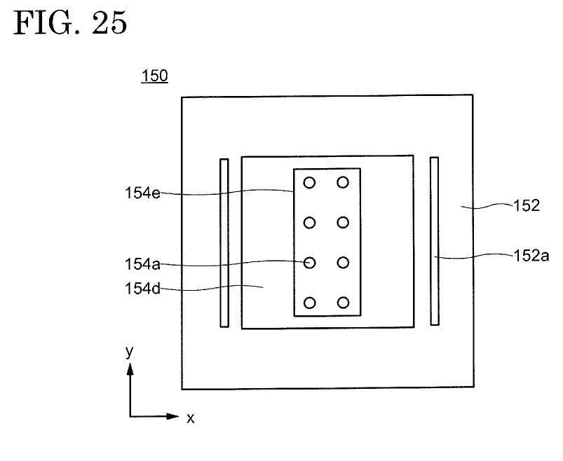

The supporting unit 152 is configured to supply a humidity-controlled gas around the collet 154. Specifically, at least one gas-supplying hole 152a is provided at the lower surface of the supporting unit 152 as shown in FIG. 4, FIG. 23, and FIG. 7. The at least one gas-supplying hole 152a may include a plurality of gas-supplying holes 152a. When providing a plurality of gas-supplying holes 152a, the plurality of gas-supplying holes 152a may be provided so as to surround the collet 154. There is no restriction on the shape of the gas-supplying holes 152a (shape at the lower surface 152b), which may be a circle, an ellipse, or a polygon including a regular square, a rectangle, and the like. The aspect ratio of the shape of the gas-supplying hole 152a may also be determined arbitrarily. Therefore, the shape of the gas-supplying hole 152a may be slit-shaped as shown in FIG. 25.

As shown in FIG. 8, the gas-supplying hole 152a is connected to the gas-supplying source 144 via a gas flow path 152cprovided in the supporting unit 152. The gas-supplying source 144 is configured to supply the humidity-controlled gas. Specifically, the gas-supplying source 144 is configured to supply a gas with a relative humidity of equal to or less than 20%, equal to or less than 15%, or equal to or less than 10%. The lower limit of the relative humidity of the supplied gas may be selected from a range equal to or greater than 0% and equal to or less than 10%. The supplied gas includes one or more selected from nitrogen, oxygen, argon, and helium. For example, the supplied gas may be air with a relative humidity of 20% or less. This feature allows the gas to be supplied from the outside of the contact surface of the collet 154, i.e., from an area surrounding the contact surface of the collet 154.

Here, the mounting head 150 is configured so that, in the state where the mounting head 150 is mounted on the lifting mechanism 140, the lowest portion of the supporting unit 152 (e.g., the surface where the gas-supplying hole 152a is provided) is higher than the lowest portion of the collet 154 (i.e., the vertex or the ridge of the convex portion 154e) as shown in FIG. 4 to FIG. 7. Since the lowest portion of the collet 154 is the downwardly protruding portion of the lower surface 154b serving as the contact surface with the semiconductor electronic component 160, the mounting head 150 is configured so that the protruding portion of this lower surface 154b is lower than the lowest portion of the supporting unit 152 (in the example shown in FIG. 7, the lower surface 152b). That is, the lowest portion of the collet 154 is configured to be located closer to the substrate S₂ than the lowest portion of the supporting unit 152. There is no restriction on the difference H in height between the lowest portion of the collet 154 and the lowest portion of the supporting unit 152, and the difference H is, for example, equal to or greater than 5 mm and equal to or less than 20 mm. Such a configuration not only allows a sufficient amount of humidity-controlled gas to be supplied between the mounting head 150 and the placed substrate S₂ but also enables the semiconductor electronic components 160 to be mounted onto the substrate S₂ without any bonding failure of the semiconductor electronic components 160 as described later.

### 3. Operation of Mounting Apparatus

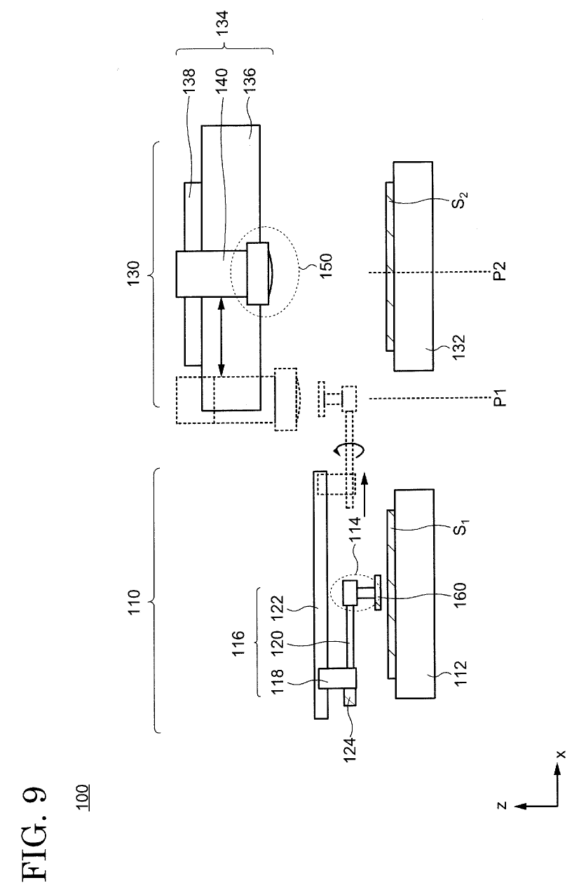

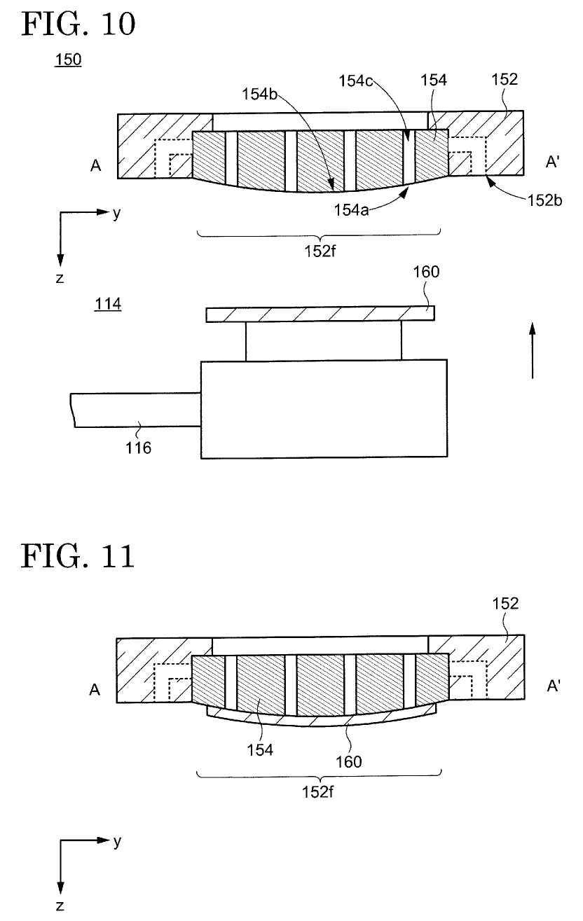

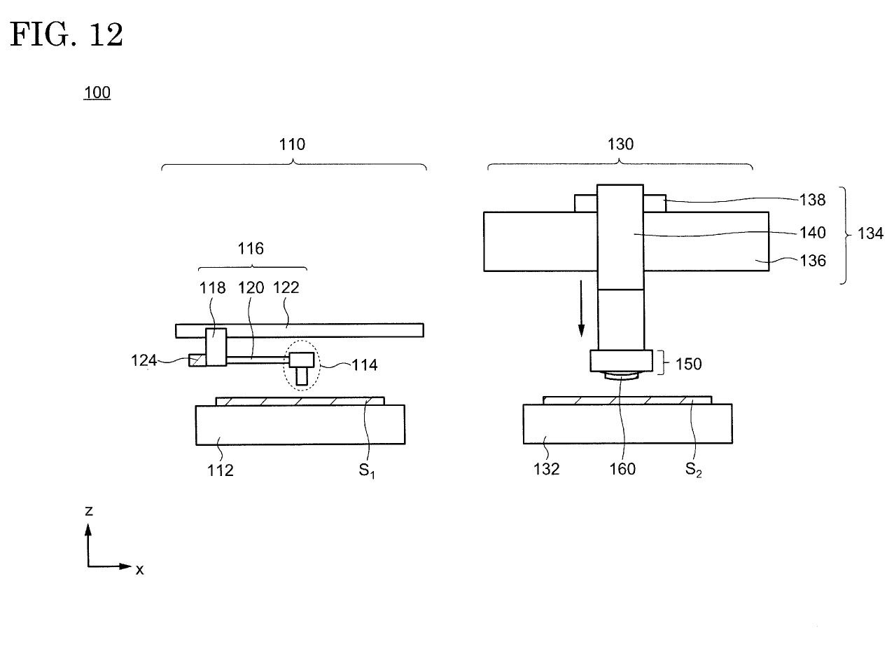

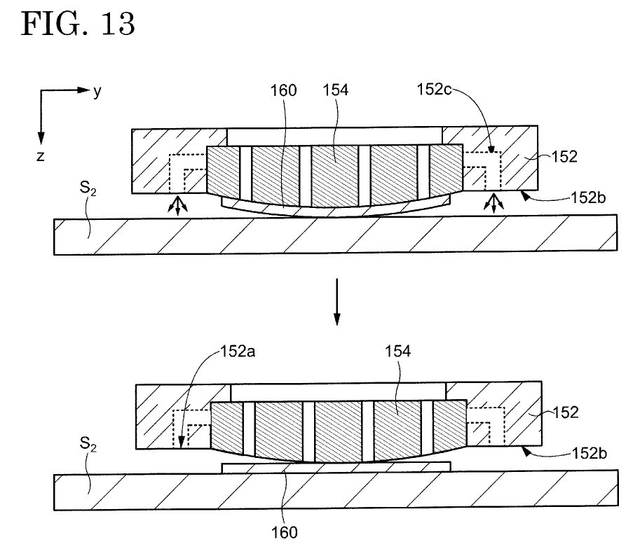

Hereinafter, the operation for mounting the semiconductor electronic component 160 onto the substrate S₂ using the mounting apparatus 100 is described using FIG. 9 to FIG. 14. FIG. 9 and FIG. 12 are schematic side views corresponding to FIG. 2, and FIG. 10, FIG. 11, and FIG. 13 are schematic cross-sectional views corresponding to FIG. 7 (note that the gas flow path 152c is shown in dotted lines for visibility). Note that since the above-mentioned pretreatment, division of the semiconductor wafer S₁, and heat treatment can be performed using known methods, the description is omitted.

First, the pick-up device 110 is used to pick up the divided semiconductor electronic components 160 one by one. Specifically, the moving mechanism 116 of the pick-up device 110 is used to position the pick-up nozzle 114 on one semiconductor electronic component 160 and the semiconductor electronic component 160 is sucked with the pick-up nozzle 114 as shown in FIG. 9. At this time, a pin which is not illustrated may be used to raise one semiconductor electronic component 160 toward the side of the pick-up nozzle 114 in order to assist the suction by the pick-up nozzle 114.

In this state, the moving mechanism 116 is controlled to move the pick-up nozzle 114 toward the side of the bonding device 130 to deliver the semiconductor electronic component 160 to the delivery position P1, and the pick-up nozzle 114 is rotated 180° about the extending direction of the arm 120 or a direction parallel thereto (see curved arrows in FIG. 9). As a result, the semiconductor electronic component 160 is flipped upside down. Meanwhile, the moving mechanism 134 of the bonding device 130 is controlled to move the mounting head 150 to the delivery position P1 and place it over the pick-up nozzle 114. As a result, the mounting head 150 overlaps the pick-up nozzle 114 in the z-direction.

Thereafter, the semiconductor electronic component 160 is delivered from the pick-up nozzle 114 to the mounting head 150. Specifically, the pick-up nozzle 114 and the mounting head 150 are brought relatively close to each other as shown in FIG. 10, and the exhaust device 142 (see FIG. 7) is operated to suck the gas on the side of the lower surface 154b through the suction channels 154c of the collet 154. As a result, a negative pressure is created on the side of the lower surface 154b of the collet 154. The gas suction may start at the time when the semiconductor electronic component 160 contacts the lower surface 154b of the collet 154 or may start before or after that time. Furthermore, the suction of the pick-up nozzle 114 is stopped at, before, or after the time when the semiconductor electronic component 160 contacts the lower surface 154b of the collet 154. As a result, the semiconductor electronic component 160 is sucked and held on the lower surface 154b of the collet 154 (FIG. 11). As described above, the lower surface 154bof the convex portion 154e of the collet 154 is curved to protrude downward. Therefore, the semiconductor electronic component 160 is sucked onto the lower surface 154b of the collet 154 in a curved state such that an edge portion thereof is positioned upward compared with a center and a vicinity thereof.

Then, the moving mechanism 134 is used to move the mounting head 150 to the position where the semiconductor electronic component 160 is to be mounted onto the substrate S₂, and the lifting mechanism 140 is controlled to bring the mounting head 150 closer to the substrate S₂ as shown in FIG. 12. When the center and its vicinity of the semiconductor electronic component 160 protruding downward come into contact with the substrate S₂ (FIG. 13), the exhaust device 142 is controlled to stop the suction. As a result, the negative pressure is released, and the curved semiconductor electronic component 160 is mounted onto the substrate S₂ while changing its shape to mimic the surface of the substrate S₂. At this time, the humidity-controlled gas is discharged from the gas-supplying source 144 through the gas-supplying hole 152a via the gas flow path 152c. It is preferable to start discharging the gas before releasing the suction of the semiconductor electronic component 160 by the collet 154. The discharge of the gas may also be started simultaneously with the release of the suction of the semiconductor electronic component 160 by the collet 154. The gas discharge may be stopped at the same time or after the time when the semiconductor electronic component 160 is mounted onto the substrate S₂. Note that the time when the gas discharge is started and stopped may be optimized in advance by experimentation or the like.

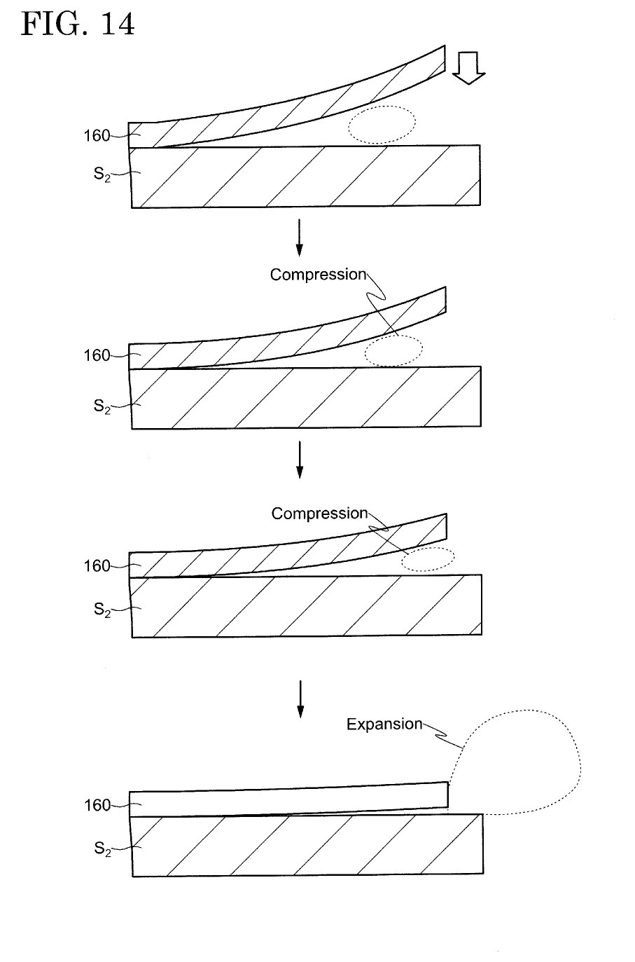

As shown in the schematic side view in FIG. 14, when the semiconductor electronic component 160 curved by the negative pressure formed on the side of the lower side 154bof the collet 154 returns to the shape mimicking the surface of the substrate S₂ (see white arrow), the gas located between the semiconductor electronic component 160 and the substrate S₂ is temporarily compressed and moves to the edge side of the semiconductor electronic component 160 (the non-curved edge side which is the edge side on the short side in this example) while being further compressed. This compressed gas expands when ejected out of the edge of the semiconductor electronic component 160. As a result, the temperature of this gas decreases due to adiabatic expansion. When the gas located between the semiconductor electronic component 160 and the substrate S₂ contains moisture at a relatively high concentration, that is, when the dew point of this gas is relatively high, the decrease in temperature caused by adiabatic expansion may condense the moisture to form fine droplets which may adhere (condense) between the semiconductor electronic component 160 and the substrate S_{2.} Since the decrease in temperature of the gas is more pronounced at the edge portions of the semiconductor electronic component 160, the adhesion of fine water droplets is particularly likely to occur at the edges and a vicinity thereof. The adhesion of water droplets causes the generation of voids between the semiconductor electronic component 160 and the substrate S₂ in the heat treatment which is the post-process of the mounting process. Such void generation causes a decrease in the bonding strength between the semiconductor electronic component 160 and the substrate S₂and electrode-electrode contact failures, resulting in a decrease in product yield.

However, as described above, when the curved semiconductor electronic component 160 is shaped to mimic the surface of the substrate S₂ and contacts the substrate S₂, the humidity-controlled gas (for example, a gas with a relative humidity of 20% or less or a dew point of 0°C or lower) is supplied from the supporting unit 152 in the mounting apparatus 100 according to an embodiment of the present disclosure. Therefore, even if the temperature is decreased due to the aforementioned adiabatic expansion, condensation of moisture is prevented, and as a result, adhesion of water to the semiconductor electronic components 160 and substrate S₂ and generation of voids resulting therefrom can be effectively prevented. As a result, it is possible to mount the semiconductor electronic components 160 with high yield.

Moreover, since the humidity-controlled gas is supplied to decrease the dew point of the gas between the semiconductor electronic component 160 and the substrate S₂, thereby preventing the condensation moisture in the mounting apparatus 100, heating of the substrate S₂ is not necessary, the bonding speed between the semiconductor electronic component 160 and the substrate S₂ doesnot need to be reduced, nor does depressurization of the space between the semiconductor electronic component 160 and the substrate S₂. Therefore, implementation of an embodiment of the present disclosure enables the production of a mounting apparatus including a bonding device with improved alignment accuracy and throughput without decreasing alignment accuracy due to fluctuations caused by heated gas, decreasing throughput due to the formation of a depressurized environment, and increasing the size and complexity of the bonding apparatus 130.

In addition, extremely small semiconductor electronic components 160 compared with semiconductor wafers can be mounted by the mounting apparatus 100. Hence, the range in which the humidity-controlled gas is supplied is limited to a relatively small area, unlike the case of mounting an entire semiconductor wafer of, for example, 8 inches (about 200 mm) to 12 inches (about 300 mm) in diameter. Therefore, not only is there no need to use a large amount of the humidity-controlled gas, but there is also no need to seal the space where the humidity-controlled gas is supplied. Hence, the mounting head 150 can be configured so that the lowest portion of the supporting unit 152 supplying the humidity-controlled gas is higher than the lowest portion of the collet 154 (see FIG. 7, FIG. 13, etc.). Even when the semiconductor electronic component 160 is further mounted onto the substrate S₂ on which the semiconductor electronic components 160 have already been mounted, this structure prevents contact and interference between the already mounted semiconductor electronic components 160 and the mounting head 150 (more specifically, the supporting unit 152). Therefore, the semiconductor electronic components 160 already mounted by the mounting head 150 do not suffer bonding defects, and as a result, it is possible to mount the semiconductor electronic components 160 onto the substrate S₂ at high density.

### Second Embodiment

In this embodiment, modified examples of the mounting head 150 described in the First Embodiment are explained. An explanation of the structures the same as or similar to those described in the First Embodiment may be omitted.

### 1. Modified Example 1

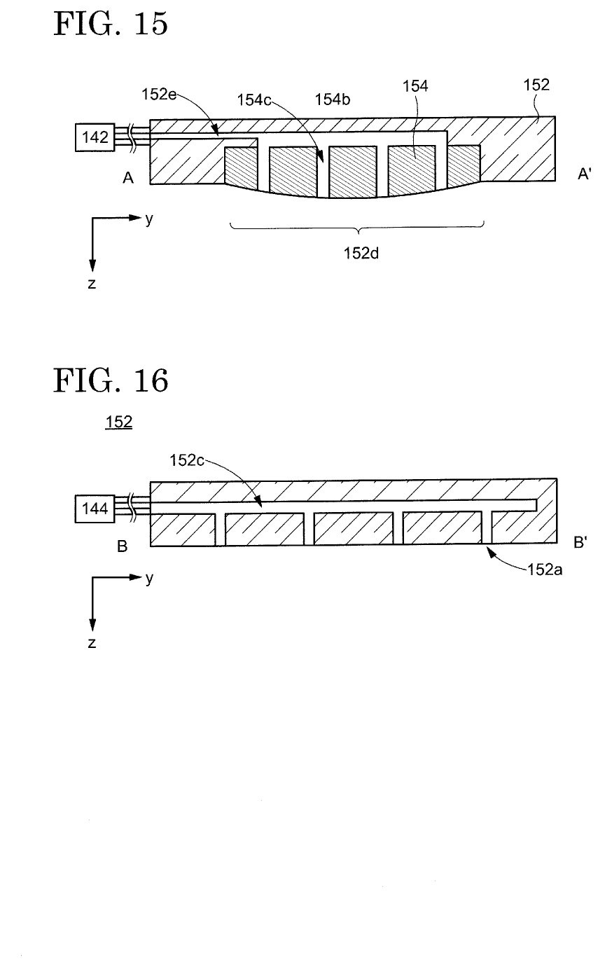

In this modified example, a mounting head 150 having a different structure from the mounting head 150 described in the First Embodiment is described. As shown in FIG. 15, the supporting unit 152 of the Modified Example 1 has a depressed portion 152d which is a bottomed hole instead of the opening 152f passing in the z-direction, and the collet 154 is accommodated in this depressed portion 152d. Since the top surface of the collet 154 is covered by the supporting unit 152 in this case, a suction path 152e connected to the suction channel 154c of the collet 154 is formed in the supporting unit 152 and connected to the exhaust device 142. The suction path 152emay reach the top of the supporting unit 152 or may reach the side surface of the supporting unit 152 as shown in FIG. 15. Similarly, the gas flow path 152cformed in the supporting unit 152 may reach the top surface of the supporting unit 152 (FIG. 8) or may reach the side surface of the supporting unit 152 as shown in FIG. 16.

### 2. Modified Example 2

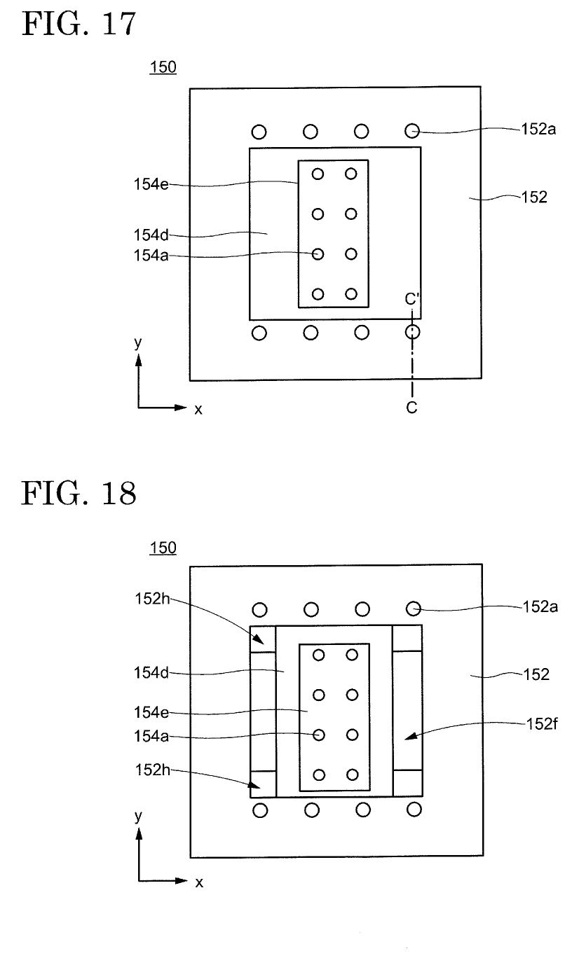

In this modified example, a different arrangement of the gas-supplying holes 152a formed in the supporting unit 152 described in the First Embodiment is explained. When the planar shape of the collet 154 is rectangular, the plurality of gas-supplying holes 152a is arranged on the side of the short side thereof as shown in FIG. 17. For example, the plurality of gas-supplying holes 152a may be arranged on a pair of straight lines extending in a direction perpendicular to the longitudinal direction (the x-direction in the example shown in FIG. 17). When the semiconductor electronic component 160 is rectangular, condensation of moisture due to the decrease in temperature caused by adiabatic expansion is likely to occur at a vicinity of the short side. Therefore, the gas can be intensively supplied to the location where condensation is likely to occur by arranging the gas-supplying holes 152a on the short side of the semiconductor electronic component 160. Furthermore, since the gas can be locally supplied, the gas consumption can also be reduced.

Furthermore, the collet 154 may be arranged so as not to block the entire opening 152f of the supporting unit 152, but to block only a part of the opening 152f as shown in FIG. 18.

### 3. Modified Example 3

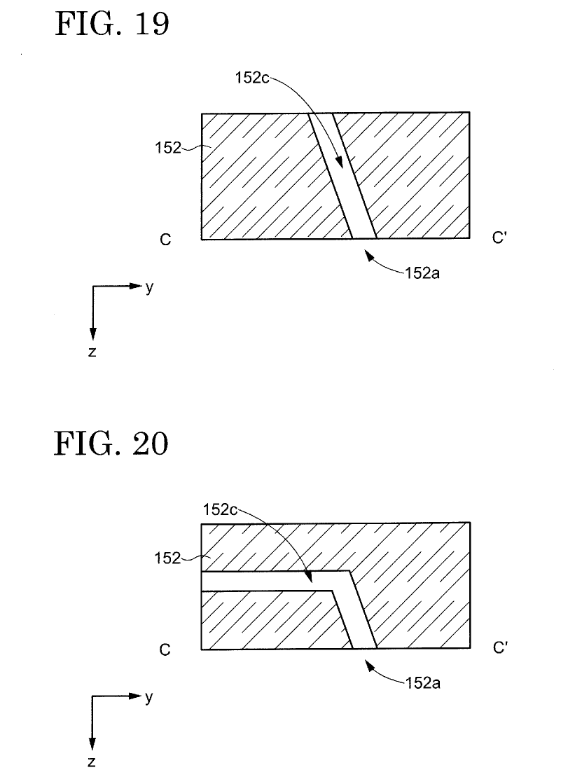

In this modified example, a different structure of the gas flow path 152c of the supporting unit 152 described in the First Embodiment is explained. As shown in the schematic views of the cross section along the chain line C-C′ in FIG. 17 (FIG. 19 and FIG. 20), the gas flow path may be configured so that at least a part thereof linearly extending from the gas-supplying hole 152ais inclined from the z-direction and the distance from the collet 154 in the y-direction decreases as it approaches the gas-supplying hole 152a in order to more efficiently supply the gas to the space between the semiconductor electronic component 160 and the substrate S₂.

### 4. Modified Example 4

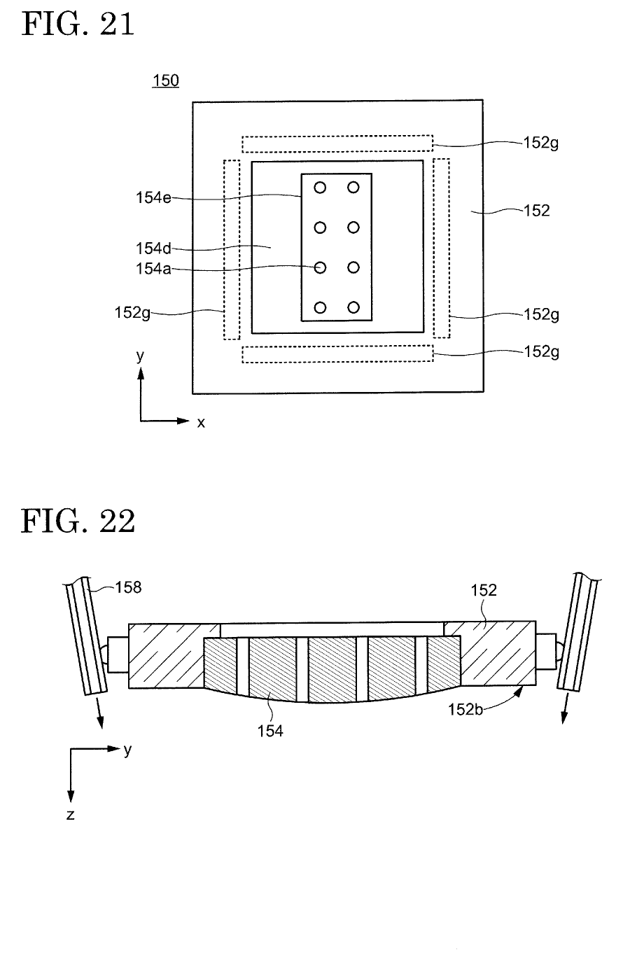

In the modified examples described above, the gas flow path 152c reaching to the gas-supplying hole 152a in the supporting unit 152 was described. However, the structure of the mounting head 150 of an embodiment of the present disclosure is not limited thereto. For example, a part of the supporting unit 152 may be formed as a porous material, and the pores of this porous material may be used as the gas flow paths 152cto supply the humidity-controlled gas. Specifically, as shown in FIG. 21, a pair of regions 152g may be formed with the porous material to sandwich the collet 154. The porous material is provided so as to pass through the collet 154 in the z-direction. That is, the porous material is disposed to extend from the top surface to the lower surface of the supporting unit 152. Preferably, the pair of regions 152gis arranged so that the longitudinal direction thereof is parallel to the short side of the semiconductor electronic component 160. Alternatively, four regions 152gmay be provided along the four sides of the collet 154, and a pair of regions 152g may be provided such that the longitudinal direction is parallel to the long side of the semiconductor electronic component 160 as shown in FIG. 21. The porous material is configured to include, for example, ceramics or a sintered metal. The humidity-controlled gas is also supplied to the porous material provided in the regions 152g.

In this modified example, it is preferred that the thickness (length in the z-direction) of the porous material provided in the supporting unit 152 be small. For example, the thickness of the supporting unit 152 may be set to be equal to or greater than 5.5 mm and equal to or less than 10 mm, the thickness of the collet 154 may be set to be less than that of the supporting unit 152 (e.g., equal to or greater than 2.5 mm and equal to or less than 10 mm), and the thickness of the porous material may be set to be equal to or less than the thickness of the supporting unit 152. The formation of a thin and porous material reduces the resistance of the gas flowing in the porous material. In addition, since the gas supplied from the porous material is supplied while being rectified by the porous material, the gas can be supplied evenly around the semiconductor electronic components 160. Therefore, an atmosphere of the humidity-controlled gas can be formed around the semiconductor electronic components 160 without any unevenness.

Alternatively, the gas flow path 152c may not be provided in the supporting unit 152, but the humidity-controlled gas may be supplied using a nozzle 158 independent from the supporting unit 152 as shown in FIG. 22. In this case, the nozzle 156 may be fixed to the supporting unit 152 or may be configured to be moved independently of the mounting head 150 using a second moving mechanism which is not illustrated. Preferably, a pair of nozzles 158 is used and tilted from the z-direction in order to supply the humidity-controlled gas to the collet 154 side. This configuration simplifies the structure of the supporting unit 152, enabling the production of the mounting head 150 at a low cost. Furthermore, the gas supply suitable for the size and shape of the semiconductor electronic component 160 can be performed by adjusting the number and direction of the nozzles 158 as appropriate.

The aforementioned modes described as the embodiments of the present disclosure can be implemented by appropriately combining with each other as long as no contradiction is caused. Furthermore, any mode which is realized by persons ordinarily skilled in the art through the appropriate combination, addition, deletion, or design change of elements or through the addition, deletion, or condition change of a process according to each embodiment is included in the scope of the present disclosure as long as they possess the concept of the present disclosure.

It is understood that another effect different from that provided by each of the aforementioned embodiments is achieved by the present disclosure if the effect is obvious from the description in the specification or readily conceived by persons ordinarily skilled in the art.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A mounting head for mounting a semiconductor electronic component onto a substrate, the mounting head comprising:
a collet having at least one suction hole at a contact surface configured to be in contact with the semiconductor electronic component so that the semiconductor electronic component is curved: and
a supporting unit supporting the collet so that the contact surface of the collet is exposed,
wherein the supporting unit is configured to supply a gas toward the substrate from outside the contact surface of the collet.

2. The mounting head according to claim 1,
wherein the supporting unit has at least one gas-supplying hole for supplying the gas.

3. The mounting head according to claim 2,
wherein the at least one gas-supplying hole includes a plurality of gas-supplying holes arranged to surround the collet.

4. The mounting head according to claim 2,
wherein a plan shape of the collet is rectangular,
wherein the at least one gas-supplying hole includes a plurality of gas-supplying holes arranged on a pair of straight lines sandwiching the collet, and
wherein the pair of straight lines is perpendicular to a longitudinal direction of the plan shape.

5. The mounting head according to claim 1,
wherein the at least one gas-supplying hole has a slit shape.

6. The mounting head according to claim 1,
wherein a portion of the supporting unit is a porous material extending from a top surface to a lower surface of the supporting unit.
